(19) United States
(12) Patent Application Publication
(10) Pub. No.: US 2022/0357491 A1
(43) Pub. Date: Nov. 10, 2022

(54) METHOD FOR PRODUCING AN OXYHYDRIDE-BASED PHOTOCHROMIC DEVICE

(71) Applicant: Institutt for Energiteknikk, Kjeller (NO)

(72) Inventors: Elbruz Murat BABA, Oslo (NO); Smagul KARAZHANOV, Oslo (NO)

(73) Assignee: Institutt for Energiteknikk, Kjeller (NO)

(21) Appl. No.: 17/623,537

(22) PCT Filed: Jul. 6, 2020
(86) PCT No.: PCT/EP2020/068991

§ 371 Date: Dec. 28, 2021

(30) Foreign Application Priority Data
Jul. 5, 2019 (NO) 20190855

(51) Int. Cl. G02B 5/23; C09K 9/00; C23C 14/34; C23C 14/06; C23C 14/58; C03C 17/22

(52) U.S. Cl. CPC G02B 5/23; C09K 9/00; C23C 14/34; C23C 14/06; C23C 14/5853; C03C 17/22; C03C 2218/154; C03C 2218/322; C03C 2217/70

(57) ABSTRACT

The present invention relates to a method for producing a photochromic oxy-hydride material as well as a photochromic component. The method comprising the steps of: —first the formation on a substrate of a layer of an essentially oxygen free rare earth metal hydride with a predetermined thickness using a physical vapor deposition process; and—second exposing the metal hydride layer to oxygen where the oxygen reacts with the metal hydride, said second step being performed in an environment having a water content defined by a water amount in air at sea level pressure with RH between >0% and 100% RH for temperatures between 0° C. and 40° C., preferably 25° Celsius.

Due to improved building techniques and the utilization of modern methods for the fabrication of glass, large windows are an increasingly common sight in modern architecture. Although the incorporation of large-area windows often results in aesthetic facades and excellent indoor lighting conditions, it can also represent a challenge in terms of energy efficiency and energy savings. Windows are, from an insulating point of view, the weakest point in a building, mainly because of their poor thermal insulation properties, but also because they allow for a significant unwanted indoors-outdoors radiative heat exchange.

Smart windows industry currently dominated by technologies which give relative control, for example by utilizing electricity or dispersed particle alignment methods. However, this control itself creates a pseudo sensation of “smart” technology because an authentic smart technology requires no control and adjust itself with the specifications it was designed according to the environment it resides. On the other hand, one promising application can be considered as smart; photochromic applications. They can adjust themselves to the environmental change without needing any control and have relatively simple structural designs compared to the complex electrochromic applications. Therefore, photochromic applications show high promise at the current industry as a genuine smart technology for future applications.

Previously, photochromic oxygen containing Yttrium hydride films, e.g. production was demonstrated in the articles by T. Mongstad et al., Solar Energy materials and Solar Cells 95 (2011) 3596-3599, “A new thin film photochromic material: Oxygen-containing yttrium hydride” and, C.C. You, Applied Physics Letters 105, 031910 (2014), “Engineering of the band gap and optical properties of thin films of yttrium hydride” and in international patent applications WO2017/125573 (IFE), WO2018/024394 (IFE) and WO2016/109651 (Saint Gobain).

The fabrication method according to the invention relates to the production method described in WO2018/024394 where oxyhydride coatings are produced as follows: an initial reactive sputter deposition of a metal hydride thin film based on a rare earth, lanthanide or alkaline metal-potentially doped by one or more other elements from the same groups, followed by a subsequent oxidation in air that aims to generate or improve any photochromic properties within the material. However, oxyhydride material tends to degrade when exposed to air or with prolonged illumination as also mentioned in WO2017/125573. Although it was postulated in the same publication that oxygen itself is the reason for increased stress levels, cracking/deformation and delamination of the material, there is no result supporting the postulate. Here we describe an improved working environment and storage conditions for oxyhydride materials.

The problems discussed above is solved using the method as described in the accompanying claims.

More specifically the present invention thus concerns a method of producing a rare earth metal oxyhydride-based photochromic device, and more specifically relates to a method of preparation, storing and working conditions for a rare earth metal oxyhydride-based (REMOH) photochromic device comprising a substrate, at least one layer including a photochromic layer having a chosen band gap range where the REMOH-based device preparation method comprises the steps of: —first the formation on a substrate of a layer of rare-earth metal hydride with a predetermined thickness using a physical vapor deposition process; and -second oxidizing the films. Distinction from the above-mentioned publications is the present patent is about finding the way to prevent degradation of the photochromic material over time and preserving photochromic kinetics. This is related to avoiding water levels that would damage the device but preserving some water levels for necessary for maintaining the photochromic kinetics, specifically bleaching (recovery when illumination stops or intensity reduces or light source wavelength composition changes), that would occur in an essentially water (water, humidity or vapour etc.) free environment. After the oxidation of the resulting rare-earth metal hydride material would be a REMOH with photochromic properties.

The invention will be described more in detail with reference to the accompanying drawings, illustrating the reason of the improvement to the device described above:

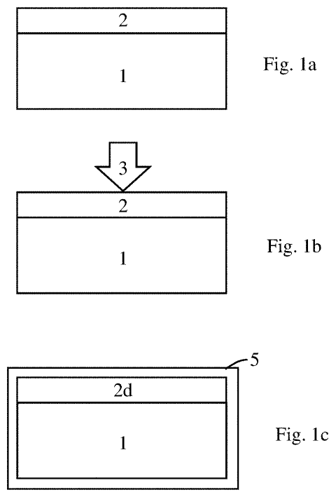

FIG. 1a-c Illustrates the production method according to the invention.

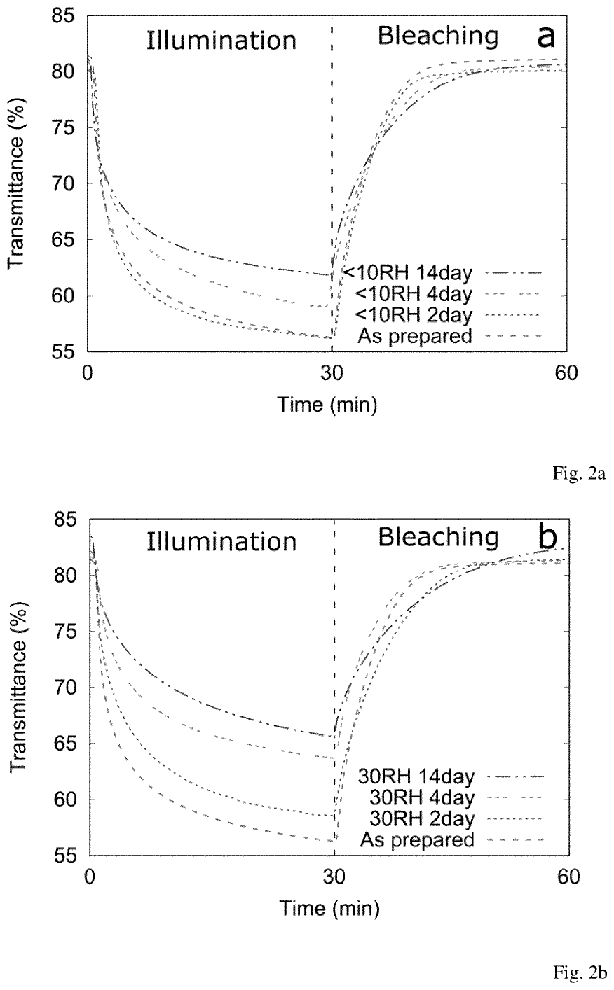

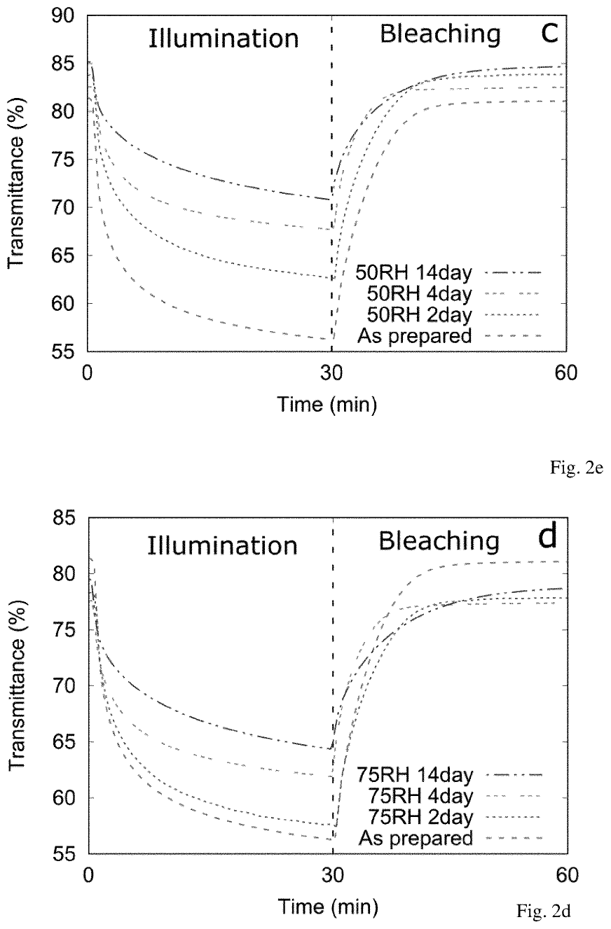

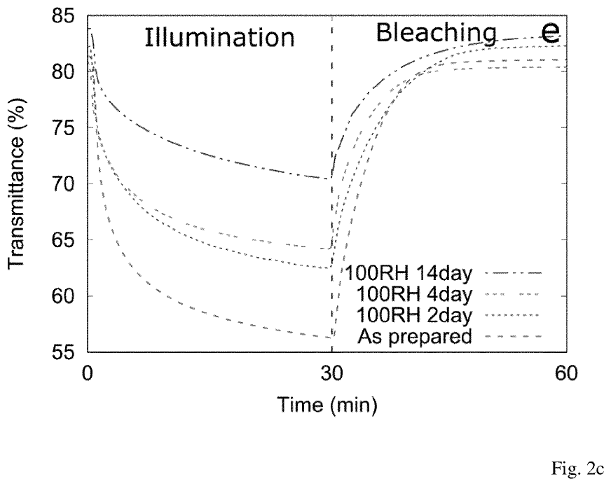

FIG. 2a-e Illustrates photochromic oxyhydride material optical kinetic degradation after stored at varying relative humidity levels.

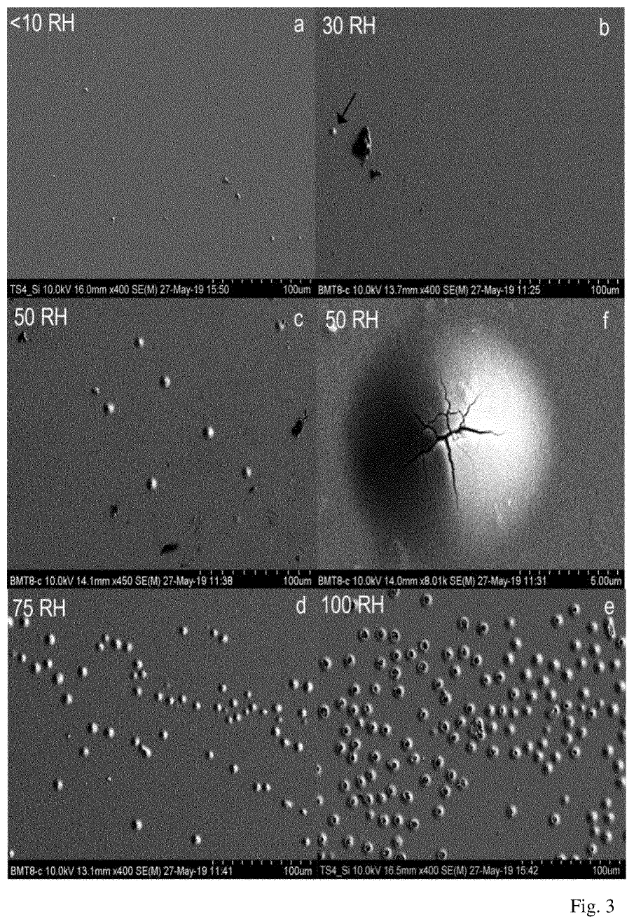

FIG. 3 Illustrates microstructure deformation, caused by varying relative humidity levels.

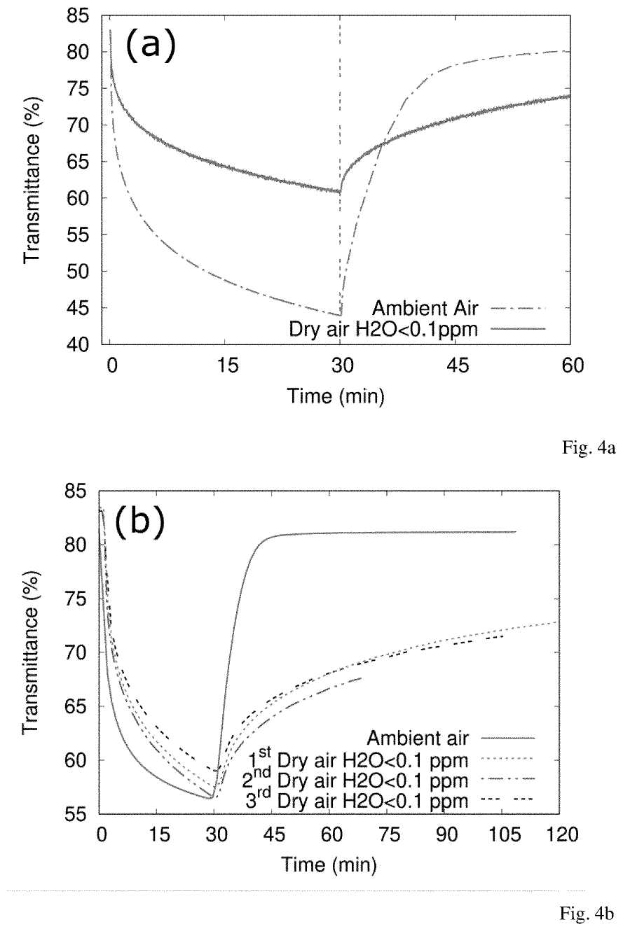

FIG. 4a,b Illustrates the photochromic kinetic difference between dry air (H2O<0.1 ppm) environment and ambient air environment.

FIG. 1a-c illustrates the production method according to the invention where the process with the deposition of an essentially oxygen-free metal hydride 2, preferably less than 0.1 ppm O₂, onto a substrate 1 (e.g. glass or a polymer-based substrate) as in FIG. 1a. The substrate is transparent where the aim of the photochromic layer is to provide a variable transmission rate depending on the light intensity. Transparent in this case also including a degree of attenuation, e.g. for permanent shading. The performance of the step of applying the metal hydride in the oxygen-free environment is known to the person skilled in the art, e.g. as discussed in WO2018/024394. The metal hydride may comprise a metal from the groups of rare earth elements, but according to the preferred embodiment of the invention the metal is yttrium, forming yttrium hydride.

In FIG. 1b the rare-earth metal hydride is exposed to an environment 3 that oxidizes the metal hydride, preferably in an environment where humidity present, forming rare-earth metal oxyhydride. Humidity in this case referring to any one of water vapour, liquid water in air or liquid water, as it is the chemical response with the water molecules that initiates the reaction. The oxidising environment should contain water in any form with a range of: water amount in air at sea level pressure with RH between >0% RH and 100% RH, preferably 60% RH, for temperatures between 0° C. and 40° C., preferably 25° Celsius.

In FIG. 1c the substrate 1 and the resulting oxyhydride is enclosed in a container 5 or similar keeping the relative humidity around the photochromic material at a low level which would contain less water in any form than the air at sea level pressure with 10% RH at 25° Celsius and above than 0.1 ppm H₂O.

According to the present invention the exposure to humidity is therefore limited afterward production so as to maintain the photochromic characteristics of the material.

The final oxygen content of the active photochromic film can be pre-defined by controlling properties like porosity and microstructure, thickness and other features of the as-deposited metal hydride as discussed in the publications mentioned above. These properties, as described below, can be achieved by tuning the deposition parameters, such as substrate temperature, substrate type, chamber pressure, sputtering power, deposition time, deposition gas flow, etc.

As mentioned above rare-earth metal oxyhydride materials, particularly yttrium oxyhydrides, are highly susceptible to environment. After oxidation at the end of the production process environmental elements, specifically water content in the air, cause cracking of the films, delamination, reducing the contrast, and damaging the photochromic kinetics. To illustrate this, we refer to the accompanying graphs in FIG. 2a-2e, an experimental procedure was designed using yttrium oxyhydride thin film coatings which were prepared according to the T. Mongstad (2011), C.C. You (2014) articles and WO2017/125573, then immediately after oxidation on air, placed in airtight boxes filled with regular air but with varying relative humidity at 25° C. temperature. FIGS. 2a-e demonstrate photochromic kinetics of stored samples in relative humidity (RH) from <10% RH to 100% RH, respectively. Photochromic kinetic studies were performed with 30 minutes of illumination using an UV Laser and 30 minutes of storing at dark for recovery (bleaching). Kinetic studies were performed after 2, 4 and 14 days storing inside the airtight boxes with respective relative humidity.

Photochromic yttrium oxyhydride coatings, initially, showing 25% contrast however, every sample demonstrates lower contrast with increased contrast loss depending on storage time (FIG. 2(a-e)). Contrast loss is strongly dependent on storage time but also water content level in the air is a factor for the speed of contrast loss. This can be observed, from FIGS. 2a-2e where contrast loss is more notable for samples stored at 100% RH after 14 days than at <10% RH and, samples stored at 100% RH lost the same contrast under 4 days as the samples stored at <10% RH but after 14 days.

FIG. 3 Scanning electron microscopy (SEM) images of microstructure deformation, caused by varying relative humidity levels; <10% (a), 30% (b), 50% (c), 75% (d) and 100% (e) after 14 days storage at room temperature. Panel (f) showing one deformation in detail. As can be seen structural change depending on the water content level in the air after 14 days of storage. Parallel to the increasing water content in air, increasing number of cracks and deformation can be observed which is correlated with contrast loss of photochromic oxyhydride material. On the other hand, absence of moisture as how conventional insulating glass units on buildings being prepared, has negative impact on the material's photochromic kinetics. In FIG. 4(a,b), photochromic kinetics of yttrium oxyhydride in dry air environment (H₂O<0.1 ppm) and ambient air environment can be observed. Bleaching speed of yttrium oxyhydride slowed considerably as a result of reduced oxidation agent presence, namely water content in air.

Due to the kinetic loss and structural deformation under air with higher water content than the water content of air with 10% RH at 25° C., storage and working environment of oxyhydride materials should therefore contain less water than the water content of air with 10% RH at 25° C. water. Additionally, due to the kinetic loss under dry air environment with water content of H₂O<0.1 ppm, storage and working environment of oxyhydride materials should therefore contain water; H₂O≥0.1 ppm. Therefore, the produced material is preferably enclosed in a container after production having the described humidity in the contained environment.

As will also be understood by the person skilled in the art a small change of humidity and temperature would have the same water content but technically different humidity. Thus a water content of air with same volume at sea level pressure that is 25° C. and 10% RH may correspond to 5% RH at 30° C. more or less equal as higher temperature can hold more water and this humidity is Relative Humidity to the same water content to this defined limit. Therefore, under some circumstances the water content corresponding to 20% at sea level pressure and is 25° C. depending on the intended use of the component, for example with varying temperatures.

To summarize the present invention relates to a method for producing a photochromic rare-earth metal oxyhydride material comprising the steps of formation on a substrate of a layer of an essentially oxygen free rare-earth metal hydride with a predetermined thickness preferably within the range of 50-1500 nm using a physical vapor deposition process. The substrate will preferably be a transparent substrate, e.g. a glass or polymer-based substrate. Following this the rare-earth metal hydride layer is exposed to air in a second step, where the metal hydride oxidises, by oxygen and water (humidity, vapour and/or moisture). The second step is performed in an environment which contain water in any form with a range of: water amount in air at sea level pressure with RH between >0% and 100% RH, preferably 60%, for temperatures between 0° C. and 40° C., preferably 25° Celsius

The metal hydride is chosen from the groups of rare earth metals, and according to the preferred embodiment of the invention an yttrium hydride.

In order to maintain the characteristics of the photochromic material the second step may be followed by a step of containing the material in a tight container or covering the photochromic material in a humidity/water tight material, sealing it from the environment.

The rare-earth metal hydride may have a porosity being above zero, i.e. it contains hollow pores, voids and/or cavities to improve the absorption of oxygen in the oxyhydride.

According to one preferred aspect of the invention a photochromic component is provided comprising a first, transparent substrate and a layer constituted metal oxyhydride enclosed in a humidity/water tight enclosure, where the oxyhydride is made from a rare-earth metal oxy-hydride, preferably an yttrium oxyhydride, which can be made using the method described above. The environment in the container comprise water content in any form, equal or less than the water content of air at sea level pressure with 20% RH at 25° C., preferably 10% RH and above 0.1 ppm H₂O.

1. A method for producing a photochromic rare-earth metal oxyhydride material, the method comprising:
first, in an environment with less than 0.1 ppm O₂, formation on a substrate of a layer of an essentially oxygen free rare-earth metal hydride with a predetermined thickness using a physical vapor deposition process; and
second, exposing the rare-earth metal hydride layer to an oxygen containing environment where the layer oxidizes and results with rare-earth metal oxyhydride, the second step being performed in an environment having water content in any form with a range defined by a water amount in air at sea level pressure with RH between >0% and 60% RH for temperatures between 0° C. and 40° C.

2. The method according to claim 1, wherein the metal in the metal hydride is yttrium.

3. The method according to claim 1, wherein the thickness of the formed rare earth metal hydride layer is within the range of 50-1500 nm using a physical vapor deposition process

4. The method according to claim 1, followed by the step of oxidizing the material in a humidity tight container.

5. The method according to claim 1, followed by the step of containing or covering the oxyhydride material in a humidity/watertight material maintaining a humidity/water content in the container at a level less than air at sea level pressure with 10% RH at 25° C. and the oxyhydride material having a water content H₂O≥0.1 ppm.

6. The method according to claim 1, wherein the metal hydride is fabricated on a transparent substrate.

7. The method according to claim 1, wherein the water content as defined in step 2 is less than 60% RH at a temperature of 25° Celsius.

8. A photochromic component comprising:
a first transparent substrate and a layer constituted rare earth metal oxyhydride produced according to the method of claim 1;
wherein the first transparent substrate is covered by a humidity/water tight container; and
wherein an environment in the container comprises water content in any form, equal or less than the water content of air at sea level pressure with 20% RH at 25° C. and the photochromic rare-earth metal oxyhydride material has a water content of H₂O≥0.1 ppm.

9. The photochromic component according to claim 8, wherein the thickness of the rare earth metal hydride layer is within the range of 50-1500 nm.

10. The photochromic component according to claim 8, wherein the rare earth metal is yttrium.

11. The photochromic component according to claim 8, wherein the container comprises water content in any form, equal or less than the water content of air at sea level pressure with 10% RH at 25° C.

12. The photochromic component according to claim 8, wherein the container comprises water content in any form, equal or less than the water content of air at sea level pressure with 5% RH at 30° C.

13. The photochromic component according to claim 8, comprising the material produced using the method according to claim 1.

14. The method according to claim 6, wherein the transparent substrate is a glass or polymer-based substrate.
